(19) United States
(12) Patent Application Publication
(10) Pub. No.: US 2024/0324261 A1
(43) Pub. Date: Sep. 26, 2024

(54) DETECTION SUBSTRATE AND DETECTION APPARATUS

(71) Applicants: Beijing BOE Sensor Technology Co., Ltd., Beijing (CN); BOE Technology Group Co., Ltd., Beijing (CN)

(72) Inventors: Shoujin CAI, Beijing (CN); Cheng LI, Beijing (CN); Jie ZHANG, Beijing (CN); Junyu WU, Beijing (CN); Yajie FENG, Beijing (CN); Jin CHENG, Beijing (CN); Dexi KONG, Beijing (CN); Shuai XU, Beijing (CN); Chuncheng CHE, Beijing (CN); Yingzi WANG, Beijing (CN)

(21) Appl. No.: 18/579,886

(22) PCT Filed: Jul. 27, 2022
(86) PCT No.: PCT/CN2022/108152

§ 371 Date: Jan. 17, 2024

(30) Foreign Application Priority Data
Aug. 16, 2021 (CN) 202110938439.9

(51) Int. Cl. H10K 39/38; H10K 39/32

(52) U.S. Cl. CPC H10K 39/38; H10K 39/32

(57) ABSTRACT

Provided in the present disclosure are a detection substrate and a detection apparatus. The detection substrate includes: a base substrate; a plurality of pixel driving circuits, which are located on the base substrate; a first insulating layer, which is located on the side, which faces away from the base substrate, of a layer where the pixel driving circuits are located, where the first insulating layer includes a plurality of first through holes; and a plurality of photosensitive devices, which are located on the side of the first insulating layer that faces away from the layer where the pixel driving circuits are located.

### CROSS REFERENCE TO RELATED APPLICATIONS

The application claims the priority to Chinese Patent Application No. 202110938439.9, filed to the China National Intellectual Property Administration on Aug. 16, 2021 and entitled “DETECTION SUBSTRATE AND DETECTION APPARATUS”, which is incorporated in its entirety herein by reference.

### TECHNICAL FIELD

The disclosure relates to the field of optical detection technology, and particularly relates to a detection substrate and a detection apparatus.

### BACKGROUND

With the development of the optical detection technology, the optical detection technology is widely used in industrial non-destructive testing, container scanning, circuit board inspection, medical care, security, industry, physiological feature recognition (such as face, fingerprint, palm print) and other fields.

### SUMMARY

Embodiments of the disclosure provide a detection substrate and a detection apparatus. The specific solution is as follows.

In an aspect, embodiments of the disclosure provide a detection substrate. The detection substrate includes a base substrate; a plurality of pixel driving circuits on the base substrate; a first insulation layer on a side of a layer including the plurality of pixel driving circuits facing away from the base substrate, where the first insulation layer includes a plurality of first through-holes; and a plurality of photosensitive devices on a side of the first insulation layer facing away from the layer including the plurality of pixel driving circuits. The photosensitive device includes a first electrode, a photoelectric conversion layer and a second electrode. The first electrode is electrically connected with the pixel driving circuit via the first through-hole, an orthographic projection of the photoelectric conversion layer on the base substrate and an orthographic projection of the first through-hole on the base substrate both are located within an orthographic projection of the first electrode on the base substrate; and the orthographic projection of the photoelectric conversion layer on the base substrate surrounds at least partially the orthographic projection of the first through-hole on the base substrate.

In some embodiments, the detection substrate according to embodiments of the disclosure further includes a plurality of gate lines and a plurality of data lines, where the gate lines and the data lines intersect for defining a plurality of pixel regions. In each pixel region, one first through-hole, and one pixel driving circuit and one photosensitive device which are electrically connected via the first through-hole are provided; where the orthographic projection of the photoelectric conversion layer on the base substrate half surrounds the orthographic projection of the first through-hole on the base substrate.

In some embodiments, in the detection substrate according to embodiments of the disclosure, the orthographic projection of the first electrode on the base substrate is square; and the orthographic projection of the first through-hole on the base substrate is located in a corner of the square orthographic projection, and the orthographic projection of the photoelectric conversion layer on the base substrate is an “L” shape and half surrounds the corner where the orthographic projection of the first through-hole is located.

In some embodiments, in the detection substrate according to embodiments of the disclosure, the pixel driving circuit includes a read transistor electrically connected with the data line and the gate line respectively. The detection substrate further includes a plurality of power lines extending in a same direction as the data lines. Where the power line is electrically connected with the pixel driving circuit, and the power line is arranged adjacent to a data line electrically connected with an adjacent pixel region. The orthographic projection of the first electrode on the base substrate partially overlaps with an orthographic projection of the power line on the base substrate and an orthographic projection of a first electrode of the read transistor on the base substrate, and does not overlap with an orthographic projection of the gate line on the base substrate, where the first electrode of the read transistor is electrically connected with the data line.

In some embodiments, in the detection substrate according to embodiments of the disclosure, the orthographic projection of the first through-hole on the base substrate is located in a corner of the orthographic projection of the first electrode on the base substrate which is opposite to an orthographic projection of the read transistor on the base substrate along the extending direction of the data lines.

In some embodiments, in the detection substrate according to embodiments of the disclosure, the pixel driving circuit further includes an amplification transistor and a read transistor. Here, a channel width-to-length ratio of the reset transistor is ((3.5˜10)/3.5+3.5), a channel width-to-length ratio of the amplification transistor is (7˜21)/7; and a channel width-to-length ratio of the read transistor is ((2˜7)/3.5+3.5).

In some embodiments, in the detection substrate according to embodiments of the disclosure, adjacent pixel regions in an extending direction of the data lines do not share a gate line, and adjacent pixel regions in an extending direction of the gate lines share a same data line. The detection substrate further includes a transparent bias layer on a side of the layer where the photosensitive device is located away from the base substrate. The transparent bias layer includes a plurality of first hollow structures and/or a plurality of second hollow structures, where the first hollow structures extend in a same direction as the gate lines, and the second hollow structures extend in a same direction as the data lines. Here, the orthographic projection of the gate line on the base substrate runs through an orthographic projection of the first hollow structure on the base substrate, and a width of the first hollow structure is greater than a sum of line widths of two adjacent gate lines and a distance between the two adjacent gate lines in an extending direction of the data lines; and the orthographic projection of data line on the base substrate runs through an orthographic projection of the second hollow structure on the base substrate, and a width of the second hollow structure is greater than a sum of a line width of the power line, a line width of the data line and a distance between the power line and the data line which are adjacent in an extending direction of the gate lines.

In some embodiments, the detection substrate according to embodiments of the disclosure further includes a second insulation layer between the layer where the photosensitive device is located and the transparent bias layer, and the second insulation layer including a plurality of second through-holes, where the transparent bias layer and the second electrode are electrically connected via the second through-hole. An orthographic projection of the second through-hole on the base substrate is located within an orthographic projection of the transparent bias layer on the base substrate, and is located within the orthographic projection of the second electrode on the base substrate.

In some embodiments, in the detection substrate according to embodiments of the disclosure, the second insulation layer includes a second planarization layer and a second protection layer which are stacked. The second through-hole includes a third sub-through-hole in the second planarization layer and a fourth sub-through-hole in the second protection layer. Here, the third sub-through-hole and the fourth sub-through-hole are connected, and an orthographic projection of the fourth sub-through-hole on the base substrate is located within an orthographic projection of the third sub-through-hole on the base substrate.

In some embodiments, in the detection substrate according to embodiments of the disclosure, a shape of the orthographic projection of the third sub-through-hole on the base substrate, a shape of the orthographic projection of the fourth sub-through-hole on the base substrate, and a shape of the orthographic projection of the second electrode on the base substrate are all the same as a shape of the orthographic projection of the photoelectric conversion layer on the base substrate.

In some embodiments, in the detection substrate according to embodiments of the disclosure, the base substrate includes a photosensitive area and a noise reduction area located at least at a side of the photosensitive area. The photosensitive device is provided in the photosensitive area, and a capacitive device is provided in the noise reduction area; and a capacitance value of the capacitive device is substantially the same as a capacitance value of the photosensitive device.

In some embodiments, in the detection substrate according to embodiments of the disclosure, the capacitive device includes a first electrode plate and a second electrode plate opposite to each other, and an insulation dielectric layer between the first electrode plate and the second electrode plate. The first electrode plate and the first electrode are in a same layer and have a same material; the second electrode plate and the transparent bias layer are in a same layer and have a same material; and the second protection layer is reused as the insulation dielectric layer.

In some embodiments, in the detection substrate according to embodiments of the disclosure, the first insulation layer includes a first planarization layer and a first protection layer arranged in stack, and the first through-hole includes a first sub-through-hole in the first planarization layer and a second sub-through-hole in the first protection layer. The first sub-through-hole and the second sub-through-hole are connected, and an orthographic projection of the second sub-through-hole on the base substrate is located within an orthographic projection of the first sub-through-hole on the base substrate.

In another aspect, embodiments of the disclosure provide a detection apparatus including the above detection substrate according to the embodiments of the disclosure.

### BRIEF DESCRIPTION OF FIGURES

FIG. 1 is a schematic structural diagram of a detection substrate according to embodiments of the disclosure.

FIG. 2 is a schematic structural diagram of a pixel region P in FIG. 1.

FIG. 3 is a cross-sectional view of the structure shown in FIG. 2.

FIG. 4 is a schematic structural diagram of a pixel driving circuit shown in FIG. 2.

FIG. 5 is a schematic structural diagram of an active layer shown in FIG. 2.

FIG. 6 is a schematic structural diagram of a gate metal layer shown in FIG. 2.

FIG. 7 is a schematic structural diagram of a gate insulation layer shown in FIG. 2.

FIG. 8 is a schematic structural diagram of an interlayer dielectric layer shown in FIG. 2.

FIG. 9 is a schematic structural diagram of a source and drain metal layer shown in FIG. 2.

FIG. 10 is a schematic structural diagram of a first insulation layer shown in FIG. 2.

FIG. 11 is a schematic structural diagram of a first electrode shown in FIG. 2.

FIG. 12 is a schematic structural diagram of a photoelectric conversion layer and a second electrode shown in FIG. 2.

FIG. 13 is a schematic structural diagram of a second insulation layer shown in FIG. 2.

FIG. 14 is a schematic structural diagram of a transparent bias layer and a shielding layer shown in FIG. 2.

FIG. 15 is another schematic structural diagram of a detection substrate according to embodiments of the disclosure.

FIG. 16 is a schematic structural diagram of a dummy pixel region D in FIG. 15.

FIG. 17 is a cross-sectional view of the structure shown in FIG. 16.

### DETAILED DESCRIPTION

For making objectives, technical solutions and advantages of embodiments of the disclosure clearer, the technical solutions of the embodiments of the disclosure will be clearly and completely described below in conjunction with the accompanying drawings in the embodiments of the disclosure. It should be noted that a size and a shape of each figure in the drawings do not reflect a true scale, but only for illustrating the disclosure. Throughout the drawings, identical or similar reference numerals denote identical or similar elements or elements having identical or similar functions.

Unless otherwise indicated, technical or scientific terms used herein should have ordinary meanings as understood by those of ordinary skill in the art to which the disclosure belongs. “First”, “second” and similar words used in the description and claims of the disclosure do not indicate any order, amount or importance, but only for distinguishing different components. “Include”, “comprise”, and other similar words indicate that elements or objects before the word include elements or objects after the word and their equivalents, without excluding other elements or objects. “Inside”, “outside”, “upper”, “lower”, etc. are only used to indicate a relative positional relation. After an absolute position of the described object changes, the relative positional relation may also change accordingly.

In the related art, in order to improve the pixel filling rate, the pixel driving circuit and the photosensitive device (PD) are usually designed in a stacked manner. That is, the pixel design adopts a method of separating the pixel driving circuit and the photosensitive device from top to bottom, and using an insulation layer to isolate the pixel driving circuit and the photosensitive device. In the specific implementation, the pixel driving circuit is first prepared on the base substrate; then an insulation layer is deposited, and the insulation layer is patterned to form a through-hole for connecting the pixel driving circuit and the photosensitive device; and finally the photosensitive device is prepared on the insulation layer, so that the photosensitive device covers the through-hole, and is electrically connected with the pixel driving circuit through the through-hole. However, the insulation layer is thick. In order to ensure good electrical connection between the pixel driving circuit and the photosensitive device, the through-holes in the insulation layer need to be larger. In this way, the photoelectric conversion layer of the photosensitive device will cover the steep slope at the through-hole, which will cause excessive leakage and cause the collected image to be filled with white spots on the screen.

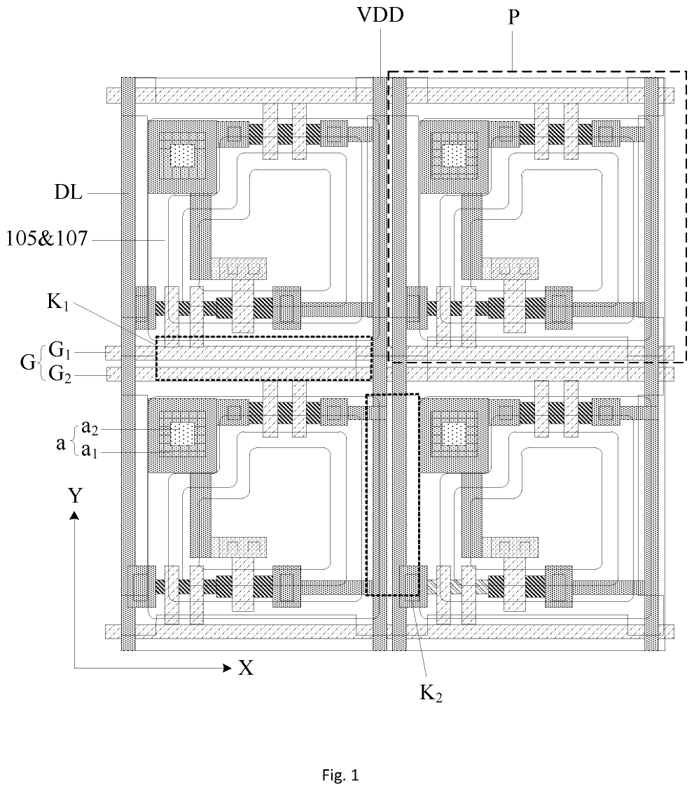

To solve at least the technical problems existing in the related art, embodiments of the disclosure provide a detection substrate. As shown in FIGS. 1-3, the detection substrate includes:
a base substrate 101;
a plurality of pixel driving circuits 102 disposed on the base substrate 101;
a first insulation layer 103 disposed on a side of a layer including the plurality of pixel driving circuits 102 facing away from the base substrate 101, where the first insulation layer includes a plurality of first through-holes a; optionally, the first insulation layer 103 includes a first planarization layer 1031 and a first protection layer 1032 arranged in stack; and the first through-hole a includes a first sub-through-hole a₁ in the first planarization layer 1031 and a second sub-through-hole a₂ in the first protection layer 1032; where, the first sub-through-hole a₁ and the second sub-through-hole a₂ are connected, and an orthographic projection of the second sub-through-hole a₂ on the base substrate 101 is located within an orthographic projection of the first sub-through-hole a₁ on the base substrate 101; and
a plurality of photosensitive devices disposed on a side of the first insulation layer 103 facing away from the layer including the plurality of pixel driving circuits 102; where the photosensitive device includes a first electrode 1041, a photoelectric conversion layer 1042 and a second electrode 1043; the first electrode is electrically connected with the pixel driving circuit 102 via the first through-hole a; an orthographic projection of the photoelectric conversion layer 1042 on the base substrate 101 and an orthographic projection of the first through-hole a on the base substrate 101 are located within an orthographic projection of the first electrode 1041 on the base substrate 101; and the orthographic projection of the photoelectric conversion layer 1042 on the base substrate 101 surrounds at least partially the orthographic projection of the first through-hole a on the base substrate 101.

In the detection substrate according to the embodiments of the disclosure, the orthographic projection of the photoelectric conversion layer 1042 on the base substrate 101 encloses at least partially the orthographic projection of the first through-hole a on the base substrate 101, to allow the photoelectric conversion layer 1042 to keep off the first through-hole a, avoiding a steep stope due to that the photoelectric conversion layer 1042 covers the first through-hole, thereby ensuring the flatness of the photoelectric conversion layer 1042, reducing interface defect states, and reducing the generation of leakage current. It is beneficial to reduce the generation of white spots in the captured images, and effectively improves the quality of the captured images.

In some embodiments, the photoelectric conversion layer 1042 provided by the embodiments of the disclosure may include a P-type semiconductor layer, an I-type semiconductor layer (also called an intrinsic semiconductor layer), and an N-type semiconductor layer which are stacked. One patterning process can be used to form the photoelectric conversion layer 1042 and the second electrode 1043. Optionally, in order to reduce the leakage current, the orthographic projection of the second electrode 1043 on the base substrate 101 needs to be slightly smaller than that of the photoelectric conversion layer 1042 on the base substrate 101. For example, a direct distance between a boundary of the orthographic projection of the second electrode 1043 on the base substrate 101 and a boundary of the orthographic projection of the photoelectric conversion layer 1042 on the base substrate 101 may range from 0.5 μm to 2 μm.

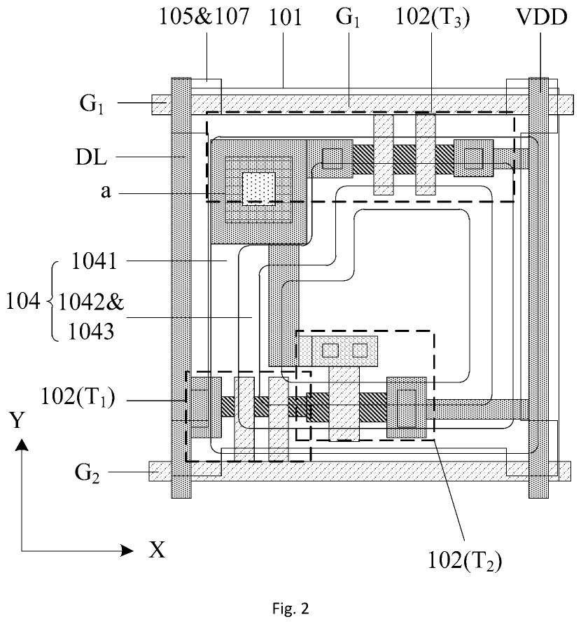

In some embodiments, the above detection substrate provided by the embodiments of the disclosure, as shown in FIGS. 1 and 2, may also include a plurality of gate lines G and a plurality of data lines DL. The plurality of gate lines G and the plurality of data lines DL intersect for defining a plurality of pixel regions P, and 2*2 pixel regions P are shown in FIG. 2. In each pixel region P, one first through-hole a, and one pixel driving circuit 102 and one photosensitive device 104 which are electrically connected via the first through-hole a are provided. Here, the orthographic projection of the photoelectric conversion layer 1042 on the base substrate 101 half surrounds the orthographic projection of the first through-hole a on the base substrate 101.

Taking into account the limitations of the process level, alignment accuracy, etc., in order to ensure that the photoelectric conversion layer 1042 can completely keep off the first through-hole a in the actual product, it is necessary to arrange a certain distance between the boundary of the orthographic projection of the photoelectric conversion layer 1042 on the base substrate 101 and the boundary of the orthographic projection of the first through-hole a on the base substrate 101. Therefore, in a case that the photoelectric conversion layer 1042 half surrounds the first through-hole a, it only needs to separate the boundary of the orthographic projection of the photoelectric conversion layer on the base substrate and the boundary of the orthographic projection of the first through-hole on the base substrate at the position where the photoelectric conversion layer 1042 half surrounds the first through-hole a by a certain distance, and thus the photoelectric conversion layer 1042 can be kept off from the first through-hole a, thereby leaving the more space for disposing the photoelectric conversion layer 1042, ensuring that a physical full well capacity of the photoelectric conversion layer 1042 is not met under a strong light condition. Of course, when an area of the pixel region P is relatively large, even if the whole boundary of the first through-hole a is kept at a certain distance from the photoelectric conversion layer 1042, it can still be ensured that there is the enough space to arrange the photoelectric conversion layer 1042 with the physical full well capacity being not met under the strong light condition. In this case, the photoelectric conversion layer 1042 can be arranged to completely surround the first through-hole a.

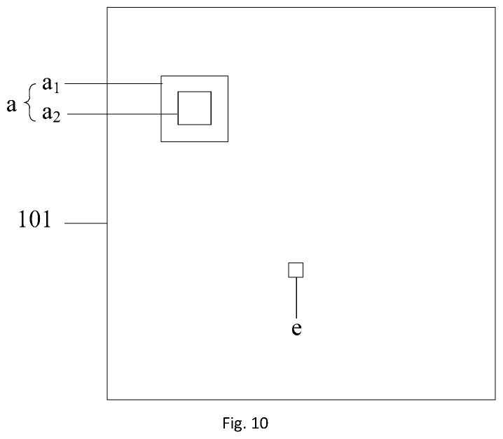

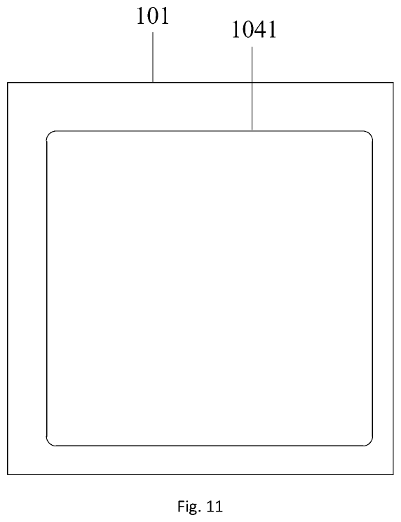

In some embodiments, in the above detection substrate provided by the embodiments of the disclosure, as shown in FIG. 2, and FIG. 10 to FIG. 12, in order to leave the enough space for the photoelectric conversion layer 1042, the orthographic projection of the first electrode 1041 on the base substrate 101 is square; the orthographic projection of the first through-hole a on the base substrate 101 is located in a corner of the square orthographic projection; and the orthographic projection of the photoelectric conversion layer 1042 on the base substrate 101 is an “L” shape and half surrounds the corner where the orthographic projection of the first through-hole a is located. Specifically, FIG. 2 shows that the orthographic projection of the first through-hole a on the base substrate is located in the upper left corner area of the orthographic projection of the first electrode 1041 on the base substrate, and the orthographic projection of the photoelectric conversion layer 1042 is an “L” shape and half surrounds the upper left corner area.

For example, a thickness of the first planarization layer 1031 is usually 2 μm˜3 μm, and correspondingly, a height of the first sub-through-hole a₁ in the first planarization layer 1031 is in a range of 2 μm˜3 μm. The first sub-through-hole a₁ is wide at the top and narrow at the bottom, and has a relatively large top aperture; and an area of the top aperture can reach 10 μm*10 μm. Taking into account the distance between the orthographic projection of the first through-hole a on the base substrate 101 and the orthographic projection of the upper left corner area where the first through-hole a on the base substrate 101 is located, the first sub-through-hole a₁ in the first planarization layer 1031 and the second sub-through-hole a₂ in the first protection layer 1032 need to occupy about 200 μm² of space. For example, the pixel region P is taken as a square which has a side length (pitch) equal to 70 μm, when the illuminance is 10 w lux and the exposure time is 100 ms, the accumulated charge amount of the pixel is about 220 fc. When converted into a filling rate, the charge amount per unit area (μm²) of the photoelectric conversion layer 1042 is calculated as 0.05 (fc/μm²). The linear voltage variation range of the existing active (active pixel sensor, APS) pixel driving circuit 102 is 1.5V. According to C=Q/U, taking U=1.5V, the minimum capacitance C of the photoelectric conversion layer 1042 can be calculated. According to the dielectric constant of the I-type semiconductor layer, it can be concluded that the required minimum area of the photoelectric conversion layer 1042 is about 1600 μm². The total area of the pixel region P with a side length of 70 μm is 4900 μm², and after excluding the area occupied by the first sub-through-hole a₁ in the first planarization layer 1031 and the second sub-through-hole a₂ in the first protection layer 1032, a space required for the spacing between the orthographic projection of the photoelectric conversion layer 1042 on the base substrate 101 and the orthographic projection of the first electrode 1041 on the base substrate 101, and a space required for the spacing between two signal lines (such as the power line VDD and the data line DL) adjacent to the adjacent pixel regions P, a space of 2200 μm² remains, which is enough to accommodate the above-mentioned photoelectric conversion layer 1042 of 1600 μm², and satisfies the requirement that a physical full well capacity of the photoelectric conversion layer 1042 is not met under the strong light condition.

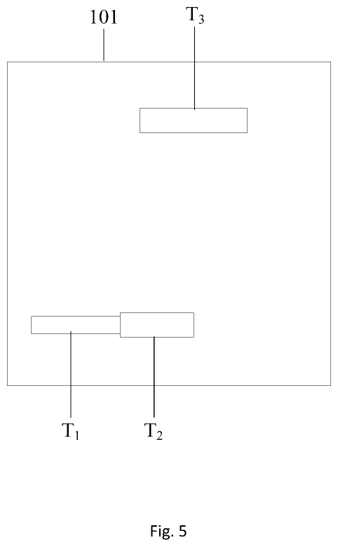

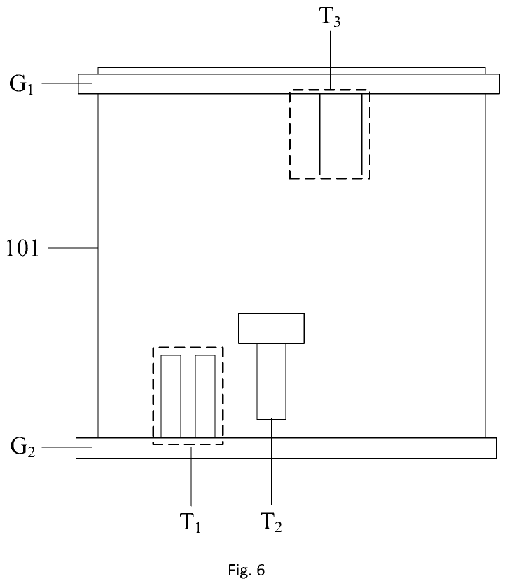

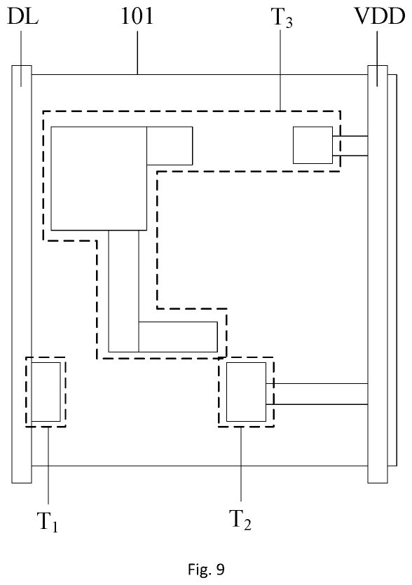

In some embodiments, in the above detection substrate provided by the embodiments of the disclosure, as shown in FIGS. 2 to 11, the pixel driving circuit 102 includes a read transistor T₁ electrically connected with the data line DL and the gate line G respectively; the detection substrate also includes a plurality of power lines VDD extending in the same direction as the data lines DL. The power line VDD is electrically connected with the pixel driving circuit 102, and the power line VDD is arranged adjacent to the data line DL electrically connected with an adjacent pixel region P. In order to avoid the mutual interfere among signals on the gate line G, the data line DL and the first electrode 1041, the orthographic projection of the first electrode 1041 on the base substrate 101 can be arranged to partially overlap with the orthographic projections of the power line VDD and the first electrode of the read transistor T₁ on the base substrate 101 respectively and not overlap with the orthographic projection of the gate line G on the base substrate 101, where the first electrode of the read transistor is electrically connected with the data line DL. In some embodiments, in order to improve the filling rate of the photoelectric conversion layer 1042, taking into account the limitations of the process level, it is preferable that the orthographic projection of the first electrode 1041 on the base substrate 101 and the orthographic projections of the gate line G and the data line DL on the base substrate 101 are spaced by a distance about 3 μm.

In some embodiments, in the above detection substrate provided by the embodiments of the disclosure, as shown in FIGS. 2 to 11, the orthographic projection of the first through-hole a on the base substrate 101 is located in a corner of the orthographic projection of the first electrode 1041 on the base substrate 101 which is opposite to the orthographic projection of the read transistor T on the base substrate 101 along the extending direction of the data lines DL. Correspondingly, the photoelectric conversion layer 1042 can be provided in other areas where the first electrode 1041 does not cover the first through-hole a, to ensure that the photoelectric conversion layer 1042 has a sufficiently large area for optical detection. Specifically, FIG. 2 shows that the orthographic projection of the read transistor on the base substrate 101 is located in the lower left corner area of the orthographic projection of the first electrode 1041 on the base substrate 101, and the orthographic projection of the first through-hole a on the base substrate 101 is located in the upper left corner area of the orthographic projection of the first electrode 1041 on the base substrate 101. Correspondingly, the photoelectric conversion layer 1042 can be provided in areas other than the upper left corner area of the first electrode 1041.

It should be noted that in the disclosure, the pixel driving circuit 102 can be a passive (passive pixel sensor, PPS) mode or an active (APS) mode, and the pixel driving circuits 102 of both modes have a read transistor T₁. Here, the APS mode is a pixel design scheme that improves image quality and reduces noise interference. The pixel driving circuit 102 of the APS mode amplifies the electrical signal provided by the photosensitive device 104 that is easily affected by the noise, so as to minimize the affection of external readout noise source related with the external chip (IC) amplifiers, which is less affected by impedance, and can be prepared in a large area. Each transistor in the pixel driving circuit 102 in the APS mode can use a low-temperature polysilicon (LTPS) process to obtain the larger carrier mobility, which is beneficial to achieving high frame rate imaging in glass-based optical detection. The pixel driving circuit 102 in the APS mode can replace the existing pixel driving circuit 102 in the amorphous silicon (a-Si)-based PPS mode, and the application scenarios and markets thereof can be improved.

In some embodiments, as shown in FIGS. 4 to 9, the pixel driving circuit 102 in the APS mode provided by the disclosure, in addition to the read transistor T₁, may also include: an amplification transistor (AMP TFT (thin film transistor)) T₂, a reset transistor (Reset TFT) T₃ and a capacitor C′. Here, the gate of the reset transistor T₃ is electrically connected with the first gate line G₁, the first electrode of the reset transistor T₃ is electrically connected with the first electrode 1041 via the first through-hole a and electrically connected with the gate of the amplification transistor T₂ via a third through-hole c, and the second electrode of the reset transistor T₃ is electrically connected with the power line VDD. The gate of the amplification transistor T₂ is also electrically connected with the first electrode 1041 via the fourth through-hole d, the first electrode of the amplification transistor T₂ is electrically connected with the second electrode of the read transistor T₂, and the second electrode of the amplification transistor T₂ is electrically connected with the power line VDD. The gate electrode of the read transistor T₁ is electrically connected with the second gate line G₂, and the first electrode of the read transistor T₁ is electrically connected with the data line DL. The capacitor C is arranged in parallel with the photosensitive device 104 (photodiode, PD). The active layer of each transistor is electrically connected with the first electrode and the second electrode of the each transistor respectively via the corresponding fifth through-hole e. In some embodiments, the first electrode of the amplification transistor T₂ and the second electrode of the read transistor T₁ may be made of the conductive active layer material.

It should be noted that each of the above-mentioned transistors may be a top-gate transistor or a bottom-gate transistor, which is not limited here. Preferably, each transistor is a low-temperature polysilicon transistor. However, in some embodiments, each transistor may also be an amorphous silicon transistor, an oxide transistor, a field effect transistor or the like. In addition, the first and second electrodes of each transistor are the drain and the source respectively. Depending on the transistor type and the input signal, functions of the first and second electrodes of each transistor can be interchanged, and no specific distinction will be made here. Generally, when the transistor is a P-type transistor, the first electrode is the source and the second electrode is the drain; and when the transistor is an N-type transistor, the first electrode is the drain and the second electrode is the source.

In the specific implementation, in FIG. 4, the reset transistor T₃ controls the gate potential of the amplification transistor T₂ to be reset, the amplification transistor T₂ amplifies the current signal output from the photosensitive device 104 (PD), and the read transistor T₁ provides the amplified current signal to the data line DL. In some embodiments, the power line VDD is provided with a direct-current potential of about +5 V, and the bias voltage V_{bias} is provided with a direct-current potential of about 0 V, so that the photosensitive device 104 (PD) is in a reverse biased state. The specific working process of the pixel driving circuit 102 shown in FIG. 4 is as follows: first, the reset transistor T₃ is turned on under the control of the first gate line G₁, so that the gate potential of the amplification transistor T₂ is reset with the signal provided by the power line VDD, and the amplification transistor T₂ works in a saturated state; then, the photosensitive device 104 (PD) enters the exposure stage, and the photosensitive device 104 (PD) is reverse-biased to generate a photocurrent signal; and finally, the read transistor T₁ is turned on under the control of the second gate line G₂, and the external read chip (readout integrated circuit, ROIC) reads the amount of the gate potential change (equivalent to the current signal on the path between the amplification transistor T₂ and the read transistor T₁) of the amplification transistor T₂ via the data line DL.

In order to improve the overall amplification performance of the pixel driving circuit 102, in the disclosure, the channel width-to-length ratio (W/L) of each transistor in the pixel driving circuit 102 shown in FIG. 4 is designed. Here, the reset transistor T₃ adopts a double-gate structure, and in order to reduce the leakage current, the channel width-to-length ratio of the reset transistor is ((3.5˜10)/3.5+3.5), such as (5/3.5+3.5). The amplification transistor T₂ works in the saturated region, which needs to have the sufficient transconductance. The channel width-to-length ratio of the amplification transistor T₂ in the disclosure can be (7˜21)/7, such as 7/7, 14/7, 21/7, etc. The read transistor T₁ works in a linear region, whose resistance should be relative small, and in the disclosure, the channel width-to-length ratio of the read transistor T₁ can be ((2˜7)/3.5+3.5), such as (2/3.5+3.5), (7/3.5+3.5), etc.

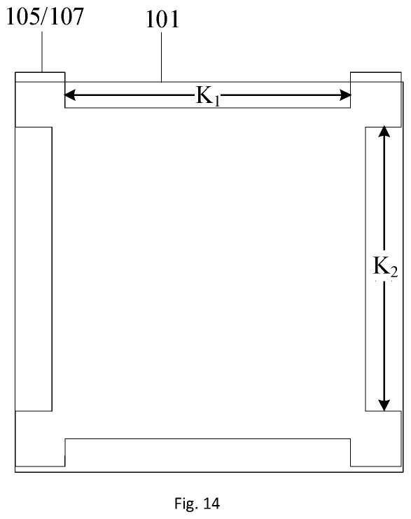

In some embodiments, in the above detection substrate provided by the embodiments of the disclosure, as shown in FIGS. 1 to 3 and FIG. 14, adjacent pixel regions P in the extending direction of the data lines DL do not share the gate line G, and adjacent pixel regions P in the extending direction of the gates line G share the data line DL. The detection substrate further includes a transparent bias layer 105 disposed on a side of the layer including the photosensitive devices 104 away from the base substrate 101. In order to minimize the crosstalk between the signal on the gate line G and/or data line DL, and the signal on the transparent bias layer 105, a plurality of first hollow structures K₁ and/or a plurality of second hollow structures K₂ are arranged in the transparent bias layer 105, where the first hollow structures K₁ have an extending direction same as the extending direction X of the gate lines, and the second hollow structures K₂ have an extending direction same as the extending direction Y of the data lines. Here, the orthographic projection of the gate line G on the base substrate 101 runs through the orthographic projection of the first hollow structure K₁ on the base substrate 101, and a width of the first hollow structure K₁ is greater than a sum of line widths of two adjacent gate lines G and a distance between the two adjacent gate lines G in the extending direction Y of the data lines. The orthographic projection of data line DL on the base substrate 101 runs through the orthographic projection of the second hollow structure K₂ on the base substrate 101, and a width of the second hollow structure K₂ is greater than a sum of a line width of the power line VDD, a line width of the data line DL and a distance between the power line VDD and the data line DL which are adjacent in the extending direction X of the gate lines.

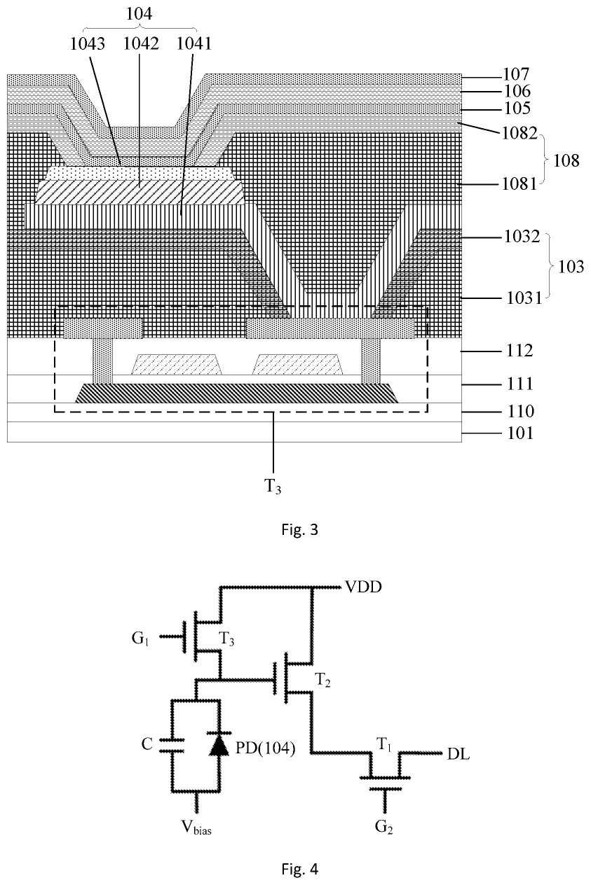

In some embodiments, as shown in FIGS. 1 to 3 and 14, the detection substrate may further include a shielding layer 107, where the shielding layer is disposed at a side of the transparent bias layer 105 facing away from the base substrate 101 and insulated with the transparent bias layer 105 via an inorganic insulation layer 106. The shielding layer 107 provides an electrostatic protection function, and in the specific implementation, the shielding layer 107 can be grounded. In addition, in order to improve the crosstalk of signals on the gate line G, the data line DL and the shielding layer 107, the shielding layer 107 can be set to have the same structure as the bias layer, that is, the patterns of the two layers are the same. Moreover, as can be seen from FIG. 3, the photoelectric conversion layer 1042 is disposed above the first insulation layer 103 without passing the area where the first through-hole a is located, ensuring a high degree of flatness of the photoelectric conversion layer 1042. The second planarization layer 1081 above the photoelectric conversion layer 1042 fills the first through-hole a, which improves the overall flatness of the transparent bias layer 105, the inorganic insulation layer 106 and the shielding layer 107 formed in the subsequent three processes, to effectively prevent the transparent bias layer 105 having a relatively small thickness from breaking.

In some embodiments, the above detection substrate provided by the embodiments of the disclosure, as shown in FIGS. 2, 3, 12 to 14, further includes a second insulation layer 108 between the layer including the photosensitive devices 104 and the transparent bias layer 105. The second insulation layer 108 includes a plurality of second through-holes b. The transparent bias layer 105 and the second electrode 1043 are electrically connected with each other via the second through-hole b. The orthographic projection of the second through-hole b on the base substrate 101 is located within the orthographic projection of the transparent bias layer 105 on the base substrate 101 and also located within the orthographic projection of the second electrode 1043 on the base substrate 101. In some embodiments, the second insulation layer 108 includes a second planarization layer 1081 and a second protection layer 1082 disposed in stack. The second through-hole b includes a third sub-through-hole b₁ in the second planarization layer 1081, and a fourth sub-through-hole b₂ in the second protection layer 1082. Here, the third sub-through-hole b₁ and the fourth sub-through-hole b₂ are connected, and an orthographic projection of the fourth sub-through-hole b₂ on the base substrate 101 is located in an orthographic projection of the third sub-through-hole b₁ on the base substrate 101.

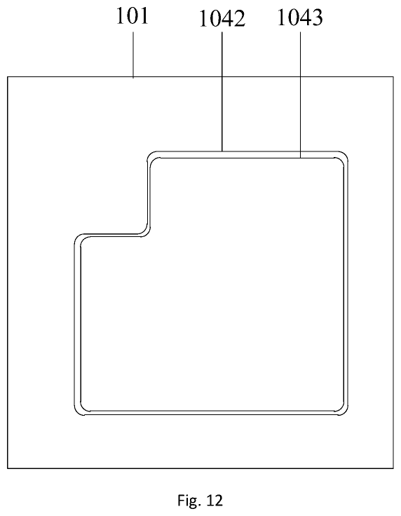

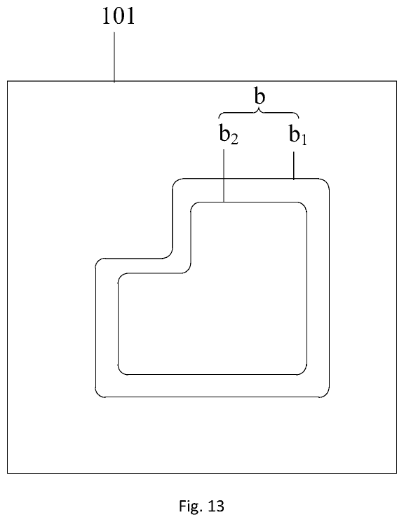

In some embodiments, in the above detection substrate provided by the embodiments of the disclosure, in order to achieve a good electrical connection between the transparent bias layer 105 and the second electrode 1043, as shown in FIGS. 12 and 13, a shape of the orthographic projection of the third sub-through-hole b₁ on the base substrate 101, a shape of the orthographic projection of the fourth sub-through-hole b₂ on the base substrate 101, and a shape of the orthographic projection of the second electrode 1043 on the base substrate 101 are all the same as a shape of the orthographic projection of the photoelectric conversion layer 1042 on the base substrate 101, for example, all are “L” shaped.

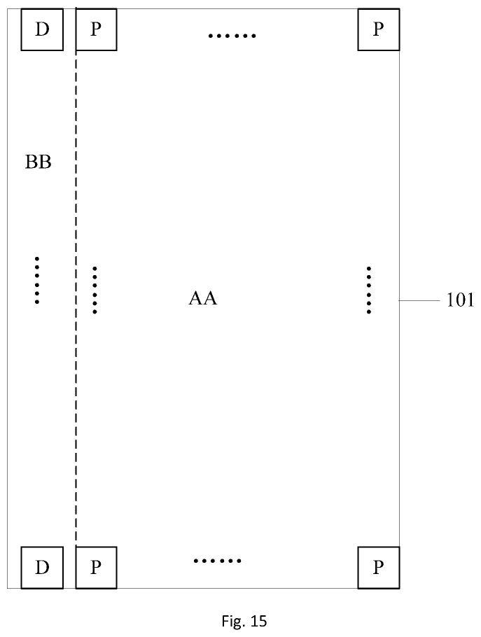

In some embodiments, in the above detection substrate provided by the embodiments of the disclosure, as shown in FIGS. 15 to 17, the base substrate 101 includes a photosensitive area AA, and a noise reduction area BB located at least at a side of the photosensitive area AA. Here, the photosensitive device 104 is provided in the photosensitive area AA, and the capacitive device 109 is provided in the noise reduction area BB. The capacitance value of the capacitive device 109 is substantially the same as the capacitance value of the photosensitive device 104.

In the related art, a metal film layer is usually provided above the photosensitive device 104 (called a Dummy pixel) in the noise reduction area BB, so that the photosensitive device 104 in the photosensitive area AA is denoised based on the photosensitive device 104 in the noise reduction area BB, thereby improving image collection quality. However, since the metal film layer has the function of reflecting light, at the boundary between the noise reduction area BB and the photosensitive area AA, there may be the light that is reflected by the film layers and is absorbed by the photosensitive device 104 in the noise reduction area BB, so that the noise situation in the dark environment cannot be reflected. In this disclosure, a capacitive device 109 with the same capacitance value as the photosensitive device 104 in the photosensitive area AA is provided in the noise reduction area BB. Since there is no photosensitive device 104 in the noise reduction area BB, no photocurrent will be generated, so that a pure dark state can be obtained to improve the noise reduction effect. In addition, in the disclosure, the metal film layer that blocks light in the noise reduction area BB in the related art is not required, which can save the process flow and reduce the production cost.

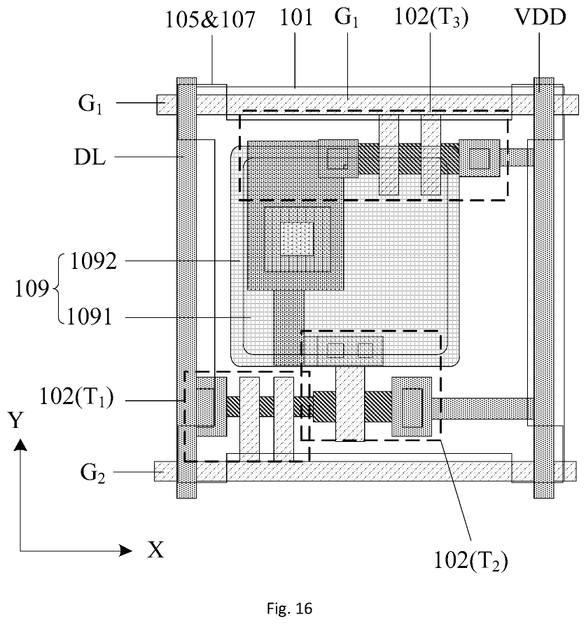

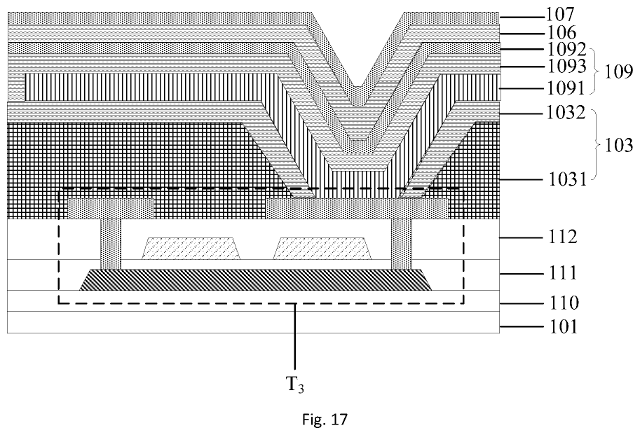

In some embodiments, in the above-mentioned detection substrate provided by the embodiments of the disclosure, as shown in FIGS. 16 and 17, the capacitive device 109 may include a first electrode plate 1091 and a second electrode plate 1092 that are opposite to each other, and an insulation dielectric layer 1093 between the first electrode plate 1091 and the second electrode plate 1092. In order to reduce film layers and save costs, the first electrode plate 1091 and the first electrode 1041 are in the same layer and have the same material, the second electrode plate 1092 and the transparent bias layer 105 are in the same layer and have the same material, and the second protection layer 1082 can be reused as the insulation dielectric layer 1093.

During the specific implementation, according to the capacitance formulas C₁=ε₁*s₁/d₁ and C₂=ε₂*s₂/d₂, where C₁ is the capacitance value of the capacitive device 109, ε₁ is the dielectric constant of the insulation dielectric layer 1093 (equivalent to the dielectric constant of the second protection layer 1082), s₁ is an area of the facing part between the first electrode plate 1091 and the second electrode plate 1092, d₁ is the thickness of the insulation dielectric layer 1093 (equivalent to the thickness of the second protection layer 1082), C₂ is the capacitance value of the photosensitive device 104, ε₂ is the dielectric constant of the I-type semiconductor layer, s₂ is an area of the facing part between the P-type semiconductor layer and the N-type semiconductor layer, d₂ is the thickness of the I-type semiconductor layer, where ε₁, d₁, ε₂, s₂ and d₂ are all known parameters. According to the above two formulas, the required area $1 of the facing part between the first electrode plate 1091 and the second electrode plate 1092 can be obtained, so that the capacitor devices 109 with the capacitance value same as that of the photosensitive device 104 can be produced.

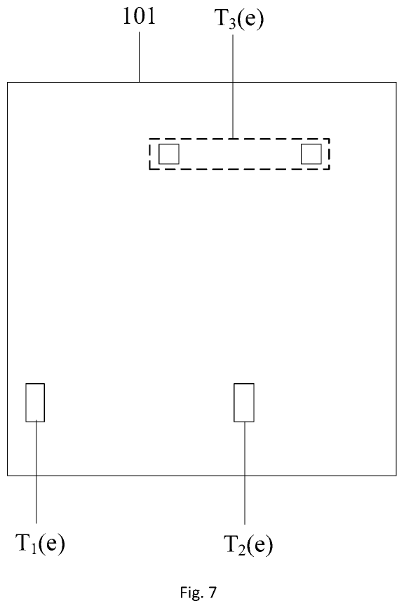

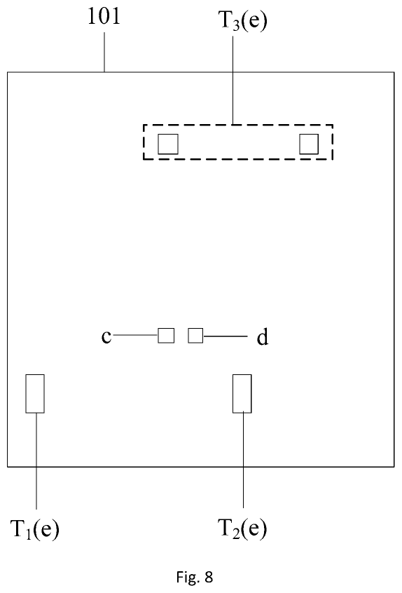

Generally, in the above detection substrate provided by the embodiments of the disclosure, as shown in FIG. 3, FIG. 7, FIG. 8, FIG. 15 and FIG. 17, the detection substrate can also include a buffer layer 110, a gate insulation layer 111 and an interlayer dielectric layer 112, etc., and other essential components in the detection substrate should be understood by those of ordinary skill in the art, which will not be described in detail here, and will not be a limitation to the disclosure.

Based on the same inventive concept, embodiments of the disclosure provide a detection apparatus, including the above-mentioned detection substrate provided by embodiments of the disclosure. Since the principle of the detection apparatus to solve the problem is similar to the principle of the above-mentioned detection substrate to solve the problem, the implementation of the detection apparatus can refer to the embodiments of the above-mentioned detection substrate, and repeated details will not be repeated.

In some embodiments, the above-mentioned detection apparatus provided by the embodiments of the disclosure can be used for identification of fingerprint, palmprint and other line patterns, or used for X-ray detection and imaging. In addition, other essential components in the detection apparatus should be understood by those of ordinary skill in the art, which will not be described in detail here, and will not be a limitation to the disclosure.

Although preferred embodiments of the disclosure have been described, those skilled in the art may make various modifications and variations of the embodiments of the disclosure without departing from the spirit and scope of the embodiments of the disclosure. Thus, where such modifications and variations of the embodiments of the disclosure fall within the scope of the claims of the disclosure and their equivalents, the present disclosure is intended to include such modifications and variations.

1. A detection substrate, comprising:
a base substrate;
a plurality of pixel driving circuits on the base substrate;
a first insulation layer on a side of a layer comprising the plurality of pixel driving circuits facing away from the base substrate, wherein the first insulation layer comprises a plurality of first through-holes; and
a plurality of photosensitive devices on a side of the first insulation layer facing away from the layer comprising the plurality of pixel driving circuits; wherein the photosensitive device comprises a first electrode, a photoelectric conversion layer and a second electrode;
wherein the first electrode is electrically connected with the pixel driving circuit via the first through-hole;
an orthographic projection of the photoelectric conversion layer on the base substrate and an orthographic projection of the first through-hole on the base substrate both are located within an orthographic projection of the first electrode on the base substrate; and
the orthographic projection of the photoelectric conversion layer on the base substrate surrounds at least partially the orthographic projection of the first through-hole on the base substrate.

2. The detection substrate according to claim 1, further comprising a plurality of gate lines and a plurality of data lines;
wherein the plurality of gate lines and the plurality of data lines intersect for defining a plurality of pixel regions;
in each of the plurality of pixel regions, one first through-hole, and one pixel driving circuit and one photosensitive device which are electrically connected via the first through-hole are provided; and
the orthographic projection of the photoelectric conversion layer on the base substrate half surrounds the orthographic projection of the first through-hole on the base substrate.

3. The detection substrate according to claim 2, wherein the orthographic projection of the first electrode on the base substrate is square;
the orthographic projection of the first through-hole on the base substrate is located in a corner of the square orthographic projection; and
the orthographic projection of the photoelectric conversion layer on the base substrate is an “L” shape and half surrounds the corner where the orthographic projection of the first through-hole is located.

4. The detection substrate according to claim 3, wherein the pixel driving circuit comprises a read transistor electrically connected with the data line and the gate line respectively;
wherein the detection substrate further comprises a plurality of power lines extending in a same direction as the data lines; and the power line is electrically connected with the pixel driving circuit, and the power line is arranged adjacent to a data line electrically connected with an adjacent pixel region;
wherein the orthographic projection of the first electrode on the base substrate partially overlaps with an orthographic projection of the power line on the base substrate and an orthographic projection of a first electrode of the read transistor on the base substrate, and does not overlap with an orthographic projection of the gate line on the base substrate;
wherein in a same pixel driving circuit, the first electrode of the read transistor is electrically connected with the data line.

5. The detection substrate according to claim 4, wherein the orthographic projection of the first through-hole on the base substrate is located in a corner of the orthographic projection of the first electrode on the base substrate which is opposite to an orthographic projection of the read transistor on the base substrate along an extending direction of the data lines.

6. The detection substrate according to claim 4, wherein the pixel driving circuit further comprises an amplification transistor and a reset transistor;
wherein a channel width-to-length ratio of the reset transistor is ((3.5˜10)/3.5+3.5);
a channel width-to-length ratio of the amplification transistor is (7˜21)/7; and
a channel width-to-length ratio of the read transistor is ((2˜7)/3.5+3.5).

7. The detection substrate according to claim 4, wherein adjacent pixel regions in an extending direction of the data lines do not share a gate line, and adjacent pixel regions in an extending direction of the gate lines share a same data line;
wherein the detection substrate further comprises a transparent bias layer on a side of the layer comprising the plurality of photosensitive devices away from the base substrate;
wherein the transparent bias layer comprises a plurality of first hollow structures and/or a plurality of second hollow structures, wherein the plurality of first hollow structures extend in a same direction as the gate lines, and the second hollow structures extend in the same direction as the data lines;
wherein the orthographic projection of the gate line on the base substrate runs through an orthographic projection of the first hollow structure on the base substrate, and a width of the first hollow structure is greater than a sum of line widths of two adjacent gate lines and a distance between the two adjacent gate lines in the extending direction of the data lines; and
the orthographic projection of data line on the base substrate runs through an orthographic projection of the second hollow structure on the base substrate, and a width of the second hollow structure is greater than a sum of a line width of the power line, a line width of the data line and a distance between the power line and the data line which are adjacent in the extending direction of the gate lines.

8. The detection substrate according to claim 7, further comprising a second insulation layer between the layer comprising the photosensitive devices and the transparent bias layer;
wherein the second insulation layer comprises a plurality of second through-holes, and the transparent bias layer and the second electrode are electrically connected via the second through-hole;
wherein an orthographic projection of the second through-hole on the base substrate is located within an orthographic projection of the transparent bias layer on the base substrate, and is located within the orthographic projection of the second electrode on the base substrate.

9. The detection substrate according to claim 8, wherein the second insulation layer comprises a second planarization layer and a second protection layer which are stacked; and
the second through-hole comprises a third sub-through-hole in the second planarization layer and a fourth sub-through-hole in the second protection layer;
wherein the third sub-through-hole and the fourth sub-through-hole are connected, and
an orthographic projection of the fourth sub-through-hole on the base substrate is located within an orthographic projection of the third sub-through-hole on the base substrate.

10. The detection substrate according to claim 9, wherein a shape of the orthographic projection of the third sub-through-hole on the base substrate, a shape of the orthographic projection of the fourth sub-through-hole on the base substrate, and a shape of the orthographic projection of the second electrode on the base substrate are all same as a shape of the orthographic projection of the photoelectric conversion layer on the base substrate.

11. The detection substrate according to claim 9, wherein the base substrate comprises a photosensitive area and a noise reduction area located at least at a side of the photosensitive area;
wherein the photosensitive device is provided in the photosensitive area, and a capacitive device is provided in the noise reduction area; and
a capacitance value of the capacitive device is substantially same as a capacitance value of the photosensitive device.

12. The detection substrate according to claim 11, wherein the capacitive device comprises a first electrode plate and a second electrode plate opposite to each other, and an insulation dielectric layer between the first electrode plate and the second electrode plate;
wherein the first electrode plate and the first electrode are in a same layer and have a same material;
the second electrode plate and the transparent bias layer are in a same layer and have a same material; and
the second protection layer is reused as the insulation dielectric layer.

13. The detection substrate according to claim 1, wherein the first insulation layer comprises a first planarization layer and a first protection layer arranged in stack; and
the first through-hole comprises a first sub-through-hole in the first planarization layer and a second sub-through-hole in the first protection layer;
wherein the first sub-through-hole and the second sub-through-hole are connected; and
an orthographic projection of the second sub-through-hole on the base substrate is located within an orthographic projection of the first sub-through-hole on the base substrate.

14. A detection apparatus, comprising the detection substrate according to claim 1.
